(19) United States
(12) Patent Application Publication
(10) Pub. No.: US 2026/0213117 A1
(43) Pub. Date: Jul. 23, 2026

(54) CHARGED PARTICLE BEAM DEVICE

(71) Applicant: Hitachi High-Tech Corporation, Tokyo (JP)

(72) Inventors: Shun KIZAWA, Tokyo (JP); Daisuke BIZEN, Tokyo (JP); Yuzuru MIZUHARA, Tokyo (JP)

(21) Appl. No.: 19/157,805

(22) PCT Filed: Apr. 20, 2023
(86) PCT No.: PCT/JP2023/015822

§ 371 Date: Aug. 19, 2025

(51) Int. Cl. H01J 37/09; H01J 37/141; H01J 37/145; H01J 37/147; H01J 37/153

(52) U.S. Cl. CPC H01J 37/09; H01J 37/141; H01J 37/145; H01J 37/1472; H01J 37/153; H01J 2237/151

(57) ABSTRACT

This charged particle beam device includes an electric field suppression electrode that has an opening for allowing a charged particle beam to pass through a charged particle optical system, and a multipole electrode that has an opening for allowing a charged particle beam to pass between a principal plane of an objective lens and the electric field suppression electrode and that generates an electrostatic deflection field or an electrostatic pole field with respect to the charged particle beam, the charged particle beam device also having: a boosting voltage source that applies a boosting voltage to an upper magnetic path of an objective lens; a retarding voltage source that applies a retarding voltage to a sample, a lower magnetic path of the objective lens, and the electric field suppression electrode; and a correction voltage source that generates an electrostatic deflection field or an electrostatic multipole field in the multipole electrode.

### TECHNICAL FIELD

The present invention relates to a charged particle beam device.

### BACKGROUND ART

In the manufacturing process of semiconductor devices, measurement and management of pattern dimensions are important for improving yield, and a scanning electron microscope, a type of charged particle beam device, is widely used for pattern dimension measurement. In order to measure the pattern dimensions of semiconductor devices, which continue to become increasingly miniaturized, with high accuracy through the use of a scanning electron microscope, it is necessary to improve the resolution of the scanning electron microscope. However, in order to reduce electron beam irradiation damage to devices, it is necessary to reduce the acceleration voltage and improve the resolution.

When performing high-resolution observations at a low acceleration voltage, a retarding method or a boosting method is used to reduce aberrations caused by objective lenses. The retarding method is a method in which a voltage (retarding voltage) of the same polarity as the voltage applied to an irradiated charged particle beam is applied to a sample so as to decelerate the irradiated charged particle beam immediately before it reaches the sample. Meanwhile, the boosting method is a method in which a voltage (boosting voltage) of the opposite polarity to the voltage applied to an irradiated electron beam is applied to an objective lens so as to accelerate irradiated charged particles when they pass through the objective lens.

While the combination of the retarding and boosting methods is useful for achieving both low acceleration and high resolution, an electric field is formed due to the potential difference between the retarding voltage and the boosting voltage, and there is a risk that the force caused by the electric field may scatter electrically-conductive foreign matter present around the sample and objective lens. When the foreign matter adheres to a circuit of a semiconductor device, the semiconductor device malfunctions. Therefore, stricter control of foreign matter is required especially in cutting-edge semiconductor processes where the minimum dimensions of circuit patterns are approaching nanometer sizes.

In order to reduce the risk of foreign matter scattering, it is necessary to suppress the electric field on the sample. Described, for example, in Patent Literature 1 is a charged particle beam device in which an electrode (third electrode 166) having the same potential as the sample is disposed below the objective lens.

### CITATION LIST

### Patent Literature

Patent Literature 1: Japanese Unexamined Patent Application Publication No. 2014-220241

### SUMMARY OF INVENTION

### Technical Problem

Low acceleration, high resolution, and reduction of risk of foreign matter scattering can be all achieved in a charged particle beam device when an electrode (hereinafter referred to as the electric field suppression electrode) having the same potential as the sample is disposed directly above the sample as described, for example, in Patent Literature 1. The reason is that the electric field suppression electrode reduces the electric field on the sample and thus suppresses the scattering of foreign matter.

However, in a case where the electric field suppression electrode is to be provided, mechanical axial misalignment during the assembly of the electric field suppression electrode cannot be avoided. Therefore, there is a concern that variation in spatial resolution between devices (instrument error) may increase. Specifically, when the central axis of the objective lens and the central axis of the electric field suppression electrode are misaligned due to axial misalignment of the electric field suppression electrode, the electric field in the objective lens is distorted to generate an electrostatic deflection field. The generated electrostatic deflection field acts to deflect the charged particle beam within the objective lens, and thus generates off-axis aberrations of the objective lens with respect to the charged particle beam. When the off-axis aberration of the objective lens becomes significant for on-axis aberrations and Airy disk caused by diffraction, the spot diameter of the charged particle beam becomes distorted to degrade the spatial resolution.

When the process of measuring the dimensions of semiconductor devices is performed by using charged particle beam devices, it is demanded that the instrument error be minimized. The reason is that, if the instrument error between the charged particle beam devices used for dimension measurement is significant, measured dimension values of each device are unreliable. For example, in the cutting-edge semiconductor processes where the minimum dimensions of circuit patterns approach nanometer sizes, it is required that management be exercised to reduce the instrument error to a sub-nanometer level.

Patent Literature 1 states that a control electrode for extracting secondary electrons from the sample is disposed closer to the sample than the electric field suppression electrode. This deteriorates the effect of reducing the electric field on the sample.

### Solution to Problem

According to an aspect of the present invention, there is provided a charged particle beam device including a sample stage, a charged particle optical system, a boosting voltage source, a retarding voltage source, and a correction voltage source. The sample stage is a stage on which a sample is placed. The charged particle optical system includes a charged particle beam source, an objective lens, an electric field suppression electrode, and a multipole electrode. The objective lens has an upper magnetic path, a lower magnetic path, and a coil, and focuses a charged particle beam emitted from the charged particle beam source on the sample. The electric field suppression electrode is disposed between the objective lens and the sample stage, positioned below the principal plane of the objective lens, and has an opening through which the charged particle beam passes. The multipole electrode is disposed between the objective lens and the electric field suppression electrode, positioned below the principal plane of the objective lens, has an opening through which the charged particle beam passes, and generates an electrostatic deflection field or an electrostatic pole field for the charged particle beam. The boosting voltage source applies a boosting voltage to the upper magnetic path. The retarding voltage source applies a retarding voltage to the sample, the lower magnetic path, and the electric field suppression electrode. The correction voltage source generates an electrostatic deflection field or an electrostatic multipole field on the multipole electrode.

### Advantageous Effects of Invention

An object of the present invention is to provide a charged particle beam device that reduces both foreign matter and instrument error. Other objects and novel features will be apparent from the description in this document and the accompanying drawings.

### BRIEF DESCRIPTION OF DRAWINGS

FIG. 1 is a diagram illustrating a configuration of a charged particle beam device.

FIG. 2 illustrates an example in which an electrostatic quadrupole deflection electrode is configured as a multipole electrode.

FIG. 3 is a diagram illustrating a mechanism for canceling an electrostatic deflection field caused by axial misalignment.

FIG. 4A illustrates an example in which the multipole electrode and an electric field suppression electrode are mounted in the charged particle beam device.

FIG. 4B illustrates an example in which the multipole electrode and an electric field suppression electrode are mounted in the charged particle beam device.

FIG. 4C illustrates an example in which the multipole electrode and an electric field suppression electrode are mounted in the charged particle beam device.

FIG. 4D illustrates an example in which the multipole electrode and an electric field suppression electrode are mounted in the charged particle beam device.

FIG. 5 illustrates an example in which an electrostatic dodecapole deflection electrode is configured as the multipole electrode.

FIG. 6A illustrates an example in which an electrostatic octupole lens is configured as the multipole electrode.

FIG. 6B illustrates an example in which an electrostatic octupole lens is configured as the multipole electrode.

FIG. 6C illustrates an example in which an electrostatic octupole lens is configured as the multipole electrode.

FIG. 7A illustrates an example in which an electrostatic dodecapole lens is configured as the multipole electrode.

FIG. 7B illustrates an example in which an electrostatic dodecapole lens is configured as the multipole electrode.

FIG. 7C illustrates an example in which an electrostatic dodecapole lens is configured as the multipole electrode.

FIG. 8 illustrates an example of a table for storing optical conditions for optical modes.

FIG. 9 illustrates an example of how a correction voltage source is controlled.

### DESCRIPTION OF EMBODIMENTS

The present disclosure proposes a charged particle beam device in which an electric field suppression electrode is preferably disposed directly above a sample to suppress an increase in the intensity of an electric field on the sample when a boosting method and a retarding method are used, and a multipole electrode for correcting an electrostatic deflection field caused by misalignment of the optical axis of the electric field suppression electrode is preferably disposed directly above the electric field suppression electrode to suppress an increase in instrument error caused by the misalignment of the optical axis of the electric field suppression electrode. The present disclosure realizes a decrease in the intensity of the electric field on the sample while suppressing the occurrence of the electrostatic deflection field caused by axial misalignment of the electric field suppression electrode and the occurrence of off-axis aberration resulting therefrom. This results in reducing both instrument error and foreign matter. Further, this eliminates the necessity of reassembling the electric field suppression electrode in order to reduce the instrument error.

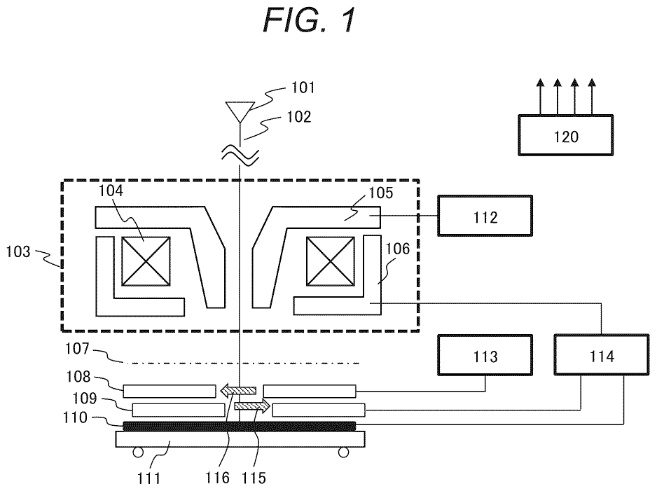

FIG. 1 is a diagram illustrating a configuration of the charged particle beam device according to an embodiment of the present invention. A charged particle optical system included in the charged particle beam device according to the present embodiment includes the electric field suppression electrode, which reduces the electric field on the sample, and the multipole electrode, which corrects the electrostatic deflection field caused by misalignment of the optical axis of the electric field suppression electrode.

A charged particle beam 102 generated by a charged particle source 101 is narrowed by an objective lens 103, passes through a multipole electrode 108 disposed below a principal plane 107 of the objective lens and through an electric field suppression electrode 109 disposed directly below the multipole electrode 108, and then is incident on a sample 110 placed on a sample stage 111. The objective lens 103 has a coil 104, an upper magnetic path 105, and a lower magnetic path 106.

Further, the charged particle beam device includes a control section 120. The control section 120 controls the charged particle optical system included in the charged particle beam device, a detection system (not depicted), and the sample stage 111. The control section 120 is, for example, a computer connected to an input device and an output device, and controls the charged particle optical system, the detection system, and the sample stage 111 in accordance with user instructions inputted via the input device, converts the result of detection by the detection system into an image, and outputs the result of measurement of the sample 110 based on the image to the output device.

A retarding voltage of −20 kV to 0 kV, which is required for high resolution, is applied from a retarding voltage source 114 to the lower magnetic path 106, the electric field suppression electrode 109, and the sample 110. Further, a boosting voltage of 0 kV to 20 kV, which is required for high resolution, is applied from a boosting voltage source 112 to the upper magnetic path 105. Therefore, an electric field directed toward the sample 110 is generated due to the difference between the boosting voltage and the retarding voltage. However, most of the generated electric field is shielded from the sample 110 by the electric field suppression electrode 109, which has the same potential as the sample 110.

However, if the central axes of the upper magnetic path 105 and electric field suppression electrode 109 do not coincide with each other, that is, if the central axis of the electric field suppression electrode 109 is misaligned with the central axis of the upper magnetic path 105, the rotational symmetry of an electrostatic lens field created by the upper magnetic path 105, to which the boosting voltage is applied, and the electric field suppression electrode 109, to which the retarding voltage is applied, is broken so as to generate an electrostatic deflection field 115. The electrostatic deflection field 115 deflects the charged particle beam 102 away from the axis of the objective lens. This may cause the off-axis aberration of the objective lens. Therefore, the present embodiment is configured such that the multipole electrode 108 connected to a correction voltage source 113 generates an electrostatic deflection field 116 for canceling the electrostatic deflection field 115. The electrostatic deflection field 115 and the electrostatic deflection field 116 cancel each other. This makes it possible to avoid the occurrence of off-axis aberration resulting from the axial misalignment of the electric field suppression electrode 109. The voltage applied from the correction voltage source 113 to the multipole electrode 108 is within a range of plus or minus 1 kV from the voltage outputted from the retarding voltage source 114. In this case, when the axial misalignment of the electric field suppression electrode 109 is approximately −100 μm to +100 μm, the electrostatic deflection fields cancel each other. However, the voltage applied from the correction voltage source 113 and the correctable amount of axial misalignment of the electric field suppression electrode 109 are merely guidelines, and may exceed the above numerical ranges.

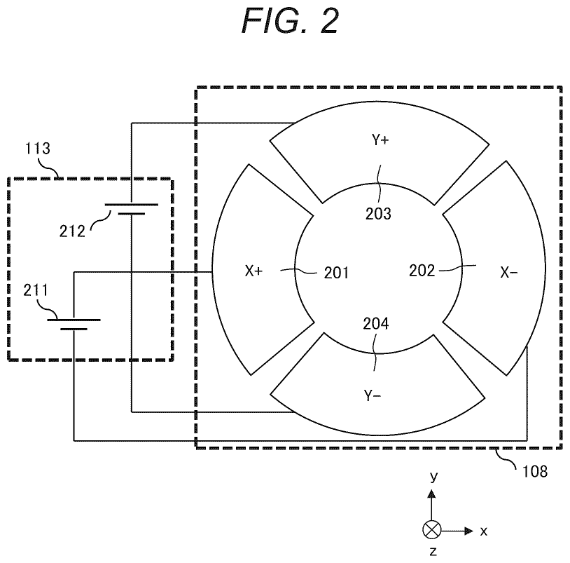

FIG. 2 illustrates an example in which an electrostatic quadrupole deflection electrode (electrodes 201-204) is used as the multipole electrode 108. The electrostatic quadrupole deflection electrode is the most basic multipole electrode that is capable of generating the electrostatic deflection field 116. The electrodes 201-204 included in the electrostatic quadrupole deflection electrode are all identical in shape and have openings for passing the charged particle beam. Further, the correction voltage source 113 includes an x-correction voltage source 211 and a y-correction voltage source 212. These correction voltage sources 211, 212 operate independently of each other. The x-correction voltage source 211 applies a voltage between the electrode 201 and the electrode 202, which face each other. The y-correction voltage source 212 applies a voltage between the electrode 203 and the electrode 204, which face each other. This makes it possible to generate electrostatic deflection fields in two linearly independent directions (x direction and y direction).

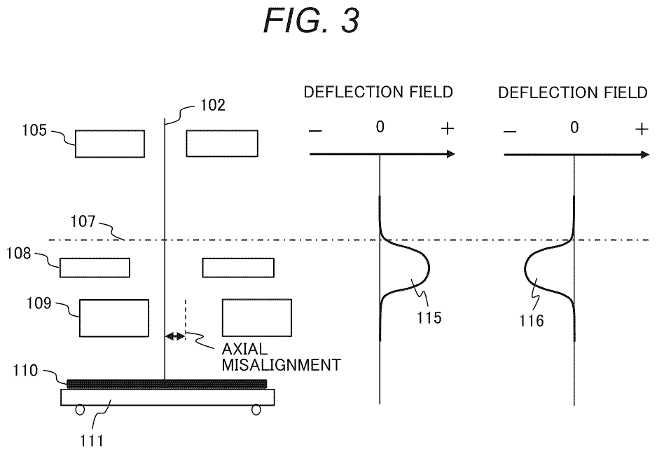

Referring now to FIG. 3, a mechanism for canceling the electrostatic deflection field 115 caused by axial misalignment will be described. When the central axis of the electric field suppression electrode 109 and the central axis of the upper magnetic path 105 are misaligned, the central axis of an electrostatic lens formed by the boosting voltage and the retarding voltage changes. This results in the generation of the electrostatic deflection field 115. The electrostatic deflection field 116, which is equal in amount and opposite in direction to the electrostatic deflection field 115, is generated by the multipole electrode 108 to let the electrostatic deflection field 115 and the electrostatic deflection field 116 cancel out each other.

As described above, both the electric field suppression electrode 109 and the multipole electrode 108 are disposed below the principal plane 107 of the objective lens. Here, the principal plane represents a reference position at which a charged particle beam incident parallel to the optical axis of the objective lens starts converging to a focal point. The reasons are as follows. If the electric field suppression electrode 109 is disposed on or above the principal plane 107 of the objective lens, the aberration of the charged particle beam increases significantly to reduce the spatial resolution. Since the electric field suppression electrode 109 and the sample 110 are set to the same potential by the retarding voltage source 114, the focusing action of the lens is inhibited in the space between the electric field suppression electrode 109 and the sample 110. Therefore, in order not to reduce the spatial resolution, it is normally necessary that the electric field suppression electrode 109 be disposed as close as possible to the sample 110. It is preferable that the height of the sample stage 111 be changeable. When the height of the sample stage 111 is changeable, the distance between the upper surface of the sample 110 and the lower surface of the electric field suppression electrode 109 can be maintained constant regardless of the structure of the sample.

Meanwhile, if the multipole electrode 108 is positioned away from the electric field suppression electrode 109 and on or above the principal plane 107 of the objective lens, the overlap gap between the spatial distribution of the electrostatic deflection field 115 generated by the electric field suppression electrode 109 and the spatial distribution of the electrostatic deflection field 116 generated by the multipole electrode 108 becomes significantly large. As a result, the electrostatic deflection field 115 is unable to cancel the electrostatic deflection field 116.

It should be noted that forming the electric field suppression electrode 109 itself by a multipole electrode makes it possible to perform the function of canceling the electrostatic deflection field at the time of axial misalignment of the electric field suppression electrode 109. However, this configuration has a problem in that the electric field cannot be shielded by the gaps between the electrodes included in the multipole electrode. Therefore, in order to suppress the instrument error due to the axial misalignment of the electric field suppression electrode while suppressing the electric field on the sample, it is desirable that a multipole electrode be provided separately from a disk-shaped (i.e., annular) electric field suppression electrode having an opening for passing the charged particle beam.

The multipole electrode 108 and the electric field suppression electrode 109 are to be formed by a conductive non-magnetic material such as single crystal silicon, molybdenum, or titanium. The reason is that the use of a magnetic material may adversely change the magnetic field distribution inside the objective lens to reduce spatial resolution. The materials mentioned above as examples are non-insulating and non-magnetic materials that have high strength and can be processed with high precision, and are thus suitable as the materials for the above electrodes.

The voltages applied to the charged particle optical system during sample observation have been described above. However, during sample exchange, the outputs of the boosting voltage source 112, correction voltage source 113, and retarding voltage source 114 are to be all at the same potential (reference potential) as a column. This prevents an electric field from being generated around the objective lens 103 and the sample 110 during sample exchange.

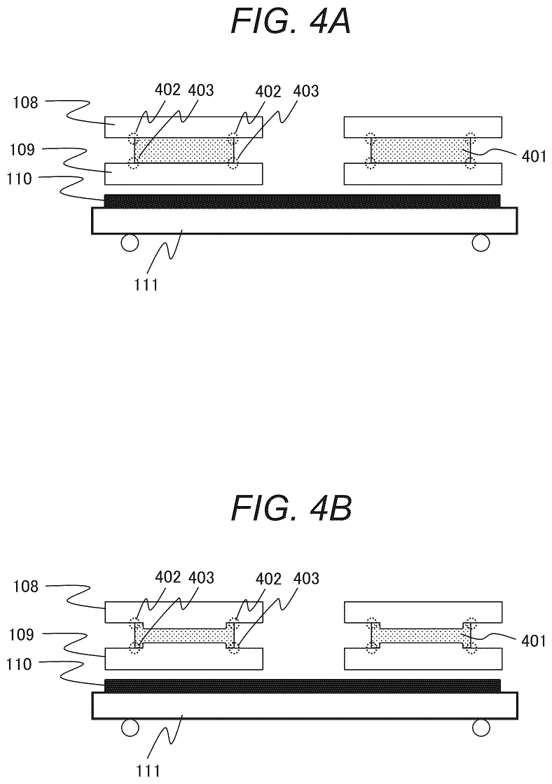

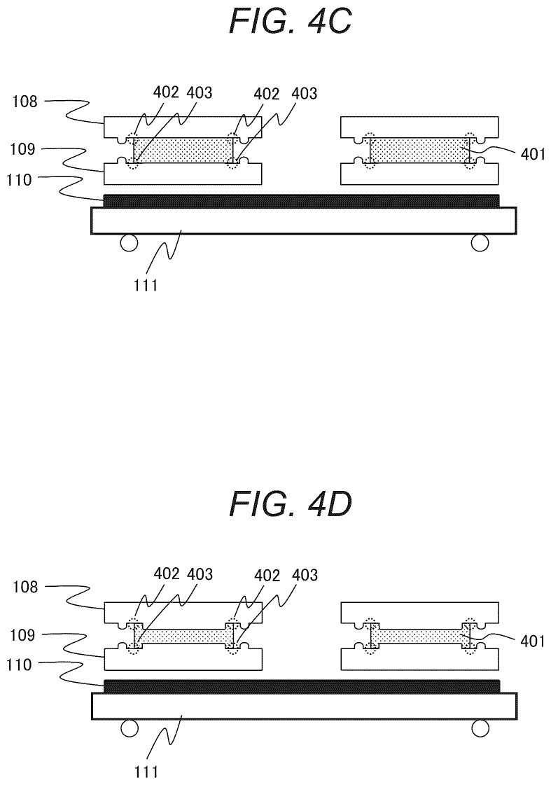

The form of implementation of the multipole electrode 108 and electric field suppression electrode 109 in the charged particle beam device will now be described with reference to FIGS. 4A to 4D. A solid insulating material 401 is sandwiched between the multipole electrode 108 and the electric field suppression electrode 109. The solid insulating material 401 not only supports the multipole electrode 108 disposed directly above the electric field suppression electrode 109, but also has the role of preventing an electrical short-circuit between the electric field suppression electrode 109 and the multipole electrode 108. In the above example, it is assumed that the multipole electrode 108, the electric field suppression electrode 109, and the solid insulating material 401 are all annular in planar shape.

The solid insulating material 401 is to be formed by an inorganic dielectric material such as silicon dioxide, aluminum oxide, steatite, sapphire, or zirconium dioxide. If the solid insulating material 401 is formed by an organic dielectric material, the vacuum level in the device may lower due to the generation of hydrocarbon gas.

### First Configuration Example

A first configuration example is depicted in FIG. 4A. In order to prevent the charged particle beam 102 from coming into contact with the solid insulating material 401, the inner diameter of the solid insulating material 401 is made larger than the inner diameters of the multipole electrode 108 and electric field suppression electrode 109. When the charged particle beam 102 comes into contact with the solid insulating material 401, the contact area becomes charged and affects the behavior of the charged particle beam. Therefore, the contact between the charged particle beam 102 and the solid insulating material 401 should be prevented. If the inner diameter of the solid insulating material 401 is equal to or smaller than the inner diameter of the multipole electrode 108 or the inner diameter of the electric field suppression electrode 109, the charged particle beam 102 and the solid insulating material 401 may come into contact with each other, causing the solid insulating material 401 to become charged. When charged, the solid insulating material 401 may cause an increase in the instrument error.

### Second Configuration Example

A second configuration example is depicted in FIG. 4B. In order to reduce the electric field at a triple point 402 where the solid insulating material 401, the multipole electrode 108, and a vacuum are in contact with each other, a protrusion is provided in the solid insulating material side region of the triple point on the surface of multipole electrode 108 that faces the electric field suppression electrode 109. Stated differently, at a portion where the solid insulating material 401 and the multipole electrode 108 are in contact with each other, a part of the multipole electrode 108 is protruded toward the solid insulating material 401. Similarly, in order to reduce the electric field at a triple point 403 where the solid insulating material 401, the electric field suppression electrode 109, and a vacuum are in contact with each other, a protrusion is provided in the solid insulating material side region of the triple point on the surface of the electric field suppression electrode 109 that faces the multipole electrode 108. Stated differently, at a portion where the solid insulating material 401 and the electric field suppression electrode 109 are in contact with each other, a part of the electric field suppression electrode 109 is protruded toward the solid insulating material 401.

### Third Configuration Example

A third configuration example is depicted in FIG. 4C. In order to reduce the electric field at the triple point 402 where the solid insulating material 401, the multipole electrode 108, and a vacuum are in contact with each other, a protrusion is provided in the vacuum side region of the triple point on the surface of multipole electrode 108 that faces the electric field suppression electrode 109. Stated differently, at a portion where the solid insulating material 401 and the multipole electrode 108 are not in contact with each other, a part of the multipole electrode 108 is protruded toward the vacuum. Similarly, in order to reduce the electric field at the triple point 403 where the solid insulating material 401, the electric field suppression electrode 109, and a vacuum are in contact with each other, a protrusion is provided in the vacuum side region of the triple point on the surface of the electric field suppression electrode 109 that faces the multipole electrode 108. Stated differently, at a portion where the solid insulating material 401 and the electric field suppression electrode 109 are not in contact with each other, a part of the electric field suppression electrode 109 is protruded toward the vacuum.

### Fourth Configuration Example

A fourth configuration example is depicted in FIG. 4D. The fourth configuration example corresponds to a structure in which the second and third configuration examples are combined.

Configurations such as those indicated by the second and third configuration examples, which reduce the electric field intensity at the triple point where two types of dielectric materials are in contact with electrodes, have the advantage of being able to prevent creeping discharge of the solid insulating material 401.

Modifications of a method used by the multipole electrode 108 to correct the axial misalignment of the electric field suppression electrode 109 are described below.

### First Modification

FIG. 2 depicts an example in which the electrostatic quadrupole deflection electrode (electrodes 201-204) generates the electrostatic deflection field 116 for canceling the electrostatic deflection field 115 that is generated due to the axial misalignment of the electric field suppression electrode 109. In the case of the electrostatic quadrupole deflection electrode (electrodes 201-204) depicted in FIG. 2, an electrostatic hexapole field is generated in addition to the electrostatic deflection field 116. The electrostatic hexapole field may cause a three-fold astigmatism and a comatic aberration, and may thus lead to an increase in instrumental error.

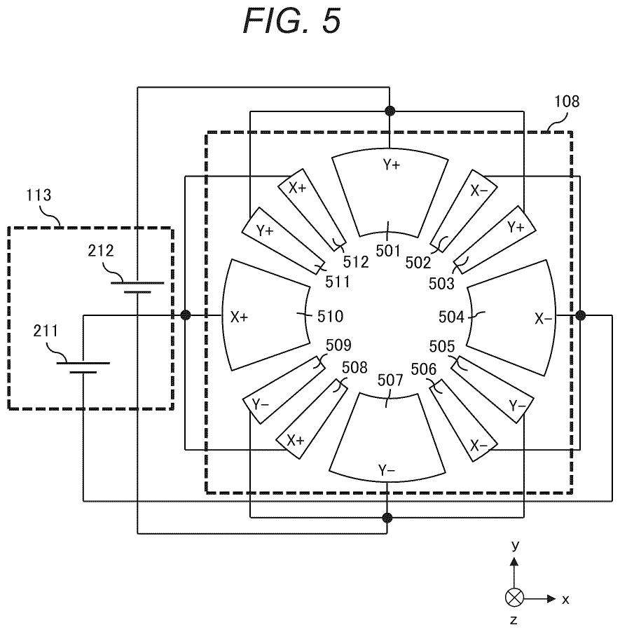

FIG. 5 depicts an example of an electrostatic dodecapole deflection electrode (electrodes 501-512) that is capable of preventing the generation of the electrostatic hexapole field, which accompanies the generation of the electrostatic deflection field 116. The electrodes included in the electrostatic dodecapole deflection electrode have a non-uniform angular distribution. The x-correction voltage source 211 applies a voltage between an electrode group (electrodes 510, 508, 512) and an electrode group (electrodes 504, 502, 506), which face each other, and the y-correction voltage source 212 applies a voltage between an electrode group (electrodes 501, 503, 511) and an electrode group (electrodes 507, 509, 505), which face each other. This makes it possible to generate electrostatic deflection fields in two linearly independent directions (x direction and y direction).

The configuration examples of the multipole electrode 108 in FIGS. 2 and 5 are examples in which an electrostatic deflection field is generated by the multipole electrode 108. However, when the correction voltage source 113 is configured so as to connect a voltage source to each electrode (pole), the multipole electrode 108 can be used as a multipole lens that generates an electrostatic pole field and an electrostatic multipole field. An example is described below.

### Second Modification

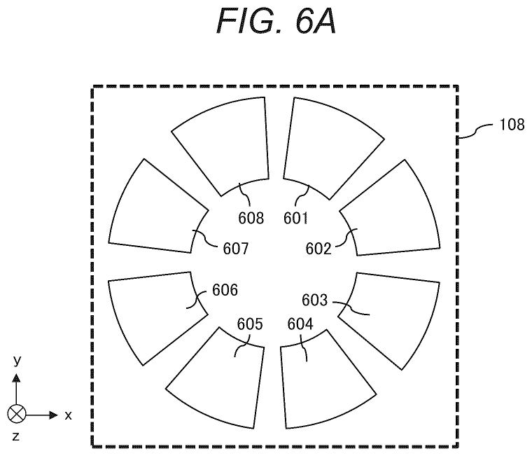

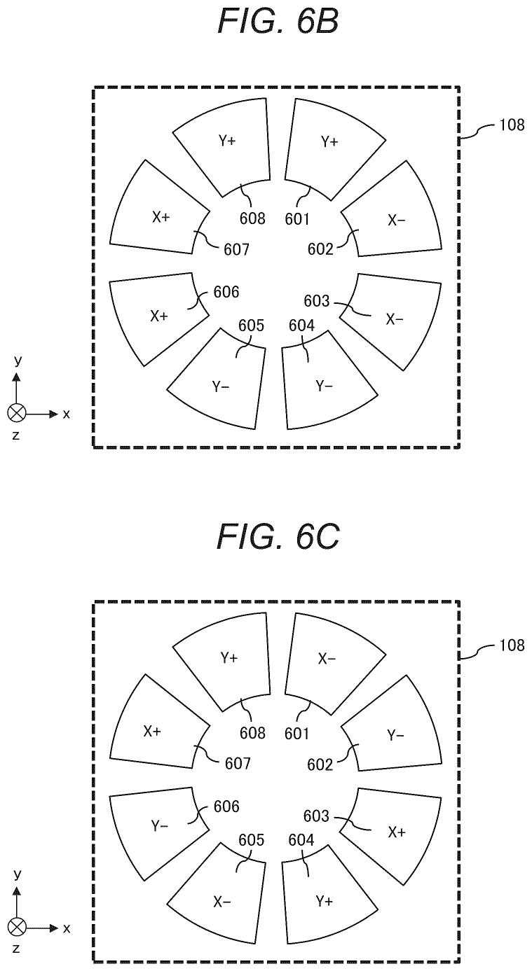

FIGS. 6A to 6C depict a configuration in which an electrostatic octupole lens (poles 601-608) is used as the multipole electrode 108. The poles 601-608 forming the electrostatic octupole lens are all identical in shape, and have the characteristic of being able to generate an electrostatic quadrupole field in addition to the electrostatic deflection field. Therefore, this configuration has the advantage of being able to correct the electrostatic quadrupole field in addition to the electrostatic deflection field caused by the axial misalignment of the electric field suppression electrode 109.

The voltage to be applied to each pole is controlled as depicted in FIG. 6B when the electrostatic deflection field is to be generated, and is controlled as depicted in FIG. 6C when the electrostatic quadrupole field is to be generated. When the voltages to be applied to the respective poles are superimposed, the electrostatic deflection field and the electrostatic quadrupole field can be generated in a superimposed manner.

### Third Modification

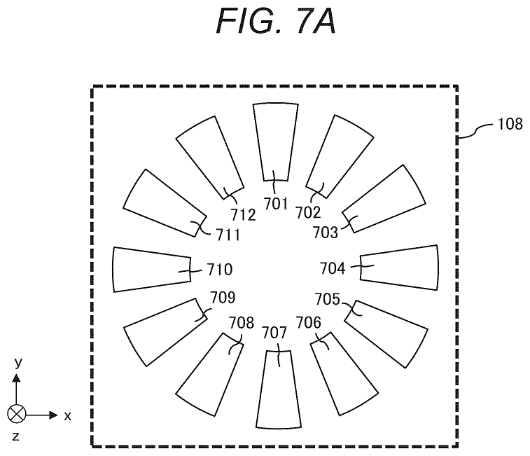

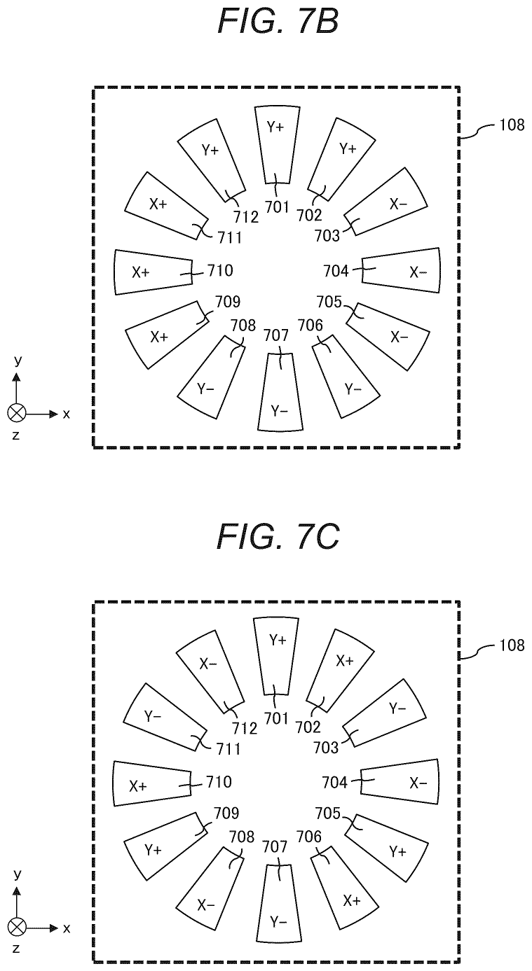

FIGS. 7A to 7C depict a configuration in which an electrostatic dodecapole lens (poles 701-712) is used as the multipole electrode 108. The poles 701-712 forming the electrostatic dodecapole lens are all identical in shape, and have the characteristic of being able to generate the electrostatic hexapole field in addition to the electrostatic deflection field. Therefore, this configuration has the advantage of being able to correct the electrostatic hexapole field in addition to the electrostatic deflection field caused by the axial misalignment of the electric field suppression electrode 109.

The voltage to be applied to each pole is controlled as depicted in FIG. 7B when the electrostatic deflection field is to be generated, and is controlled as depicted in FIG. 7C when the electrostatic hexapole field is to be generated. When the voltages to be applied to the respective poles are superimposed, the electrostatic deflection field and the electrostatic hexapole field can be generated in a superimposed manner.

As described above, the configuration of the correction voltage source 113 connected to the multipole electrode 108 and the angular distribution of the electrodes (poles) forming the multipole electrode 108 are set in accordance with the deflection field and multipole field generated by the multipole electrode 108. Further, the foregoing embodiment and modifications have been described with reference to an example in which the multipole electrode 108 has electrodes (poles) in a shape obtained by dividing an annular electrode according to a predetermined angular distribution. However, the electrodes (poles) may be configured as parallel plates.

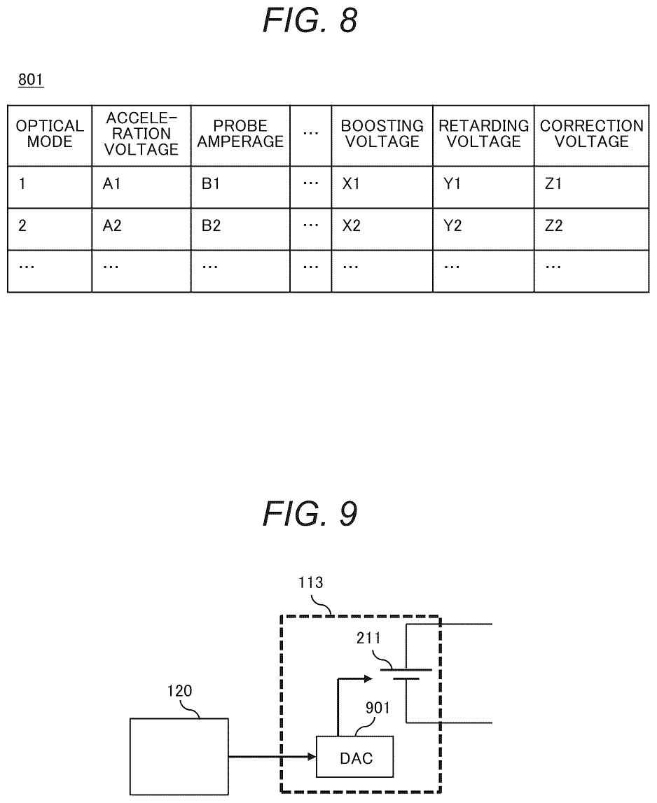

The magnitude of the electrostatic deflection field 115 caused by the axial misalignment of the electric field suppression electrode 109 varies with optical conditions. Therefore, the control section 120 of the charged particle beam device stores a table 801 depicted, for example, in FIG. 8. The table 801 registers the optical conditions for a plurality of optical modes. The voltage to be applied to the multipole electrode 108 by the correction voltage source 113 is registered in the table 801 in addition to the acceleration voltage, probe amperage, boosting voltage, and retarding voltage of the charged particle beam. In a case where the correction voltage source 113 applies a plurality of voltages, each of them is registered in the table 801.

The control section 120 observes the sample in a user-selected optical mode. In this instance, as depicted in FIG. 9, the control section 120 transmits a correction voltage control signal corresponding to the user-selected optical mode to the correction voltage source 113 in accordance with the table 801, and causes, for example, a DAC (Digital Analog Converter) 901 of the correction voltage source 113 to control the value of a voltage to be outputted from the correction voltage source 113.

The present invention is not limited to the foregoing embodiment, but can be modified in various ways. For example, the foregoing embodiment and modifications have been described in detail to facilitate the understanding of the present invention, and are not necessarily limited to a configuration that includes all the above-described component elements. Further, some component elements of an embodiment or modification can be replaced by the component elements of another embodiment or modification. Furthermore, the component elements of an embodiment or modification can be added to the component elements of another embodiment or modification. Moreover, some component elements of each embodiment or modification can be subjected to the addition of other component elements, deleted, or replaced by other component elements.

### REFERENCE SIGNS LIST

101: charged particle source
102: charged particle beam
103: objective lens
104: coil
105: upper magnetic path
106: lower magnetic path
107: principal plane of objective lens
108: multipole electrode
109: electric field suppression electrode
110: sample
111: sample stage
112: boosting voltage source
113: correction voltage source
114: retarding voltage source
115, 116: electrostatic deflection field
120: control section
201 to 204: electrostatic quadrupole deflection electrode
211: x-correction voltage source
212: y-correction voltage source
401: solid insulating material
402, 403: triple point
501 to 512: electrostatic dodecapole deflection electrode
601 to 608: electrostatic octupole lens
701 to 712: electrostatic dodecapole lens
801: table
901: DAC

1. A charged particle beam device comprising:
a sample stage on which a sample is placed;
a charged particle optical system that includes a charged particle beam source, an objective lens, an electric field suppression electrode, and a multipole electrode, the objective lens having an upper magnetic path, a lower magnetic path, and a coil, and focusing a charged particle beam emitted from the charged particle beam source on the sample, the electric field suppression electrode being disposed between the objective lens and the sample stage, positioned below the principal plane of the objective lens, and having an opening through which the charged particle beam passes, the multipole electrode being disposed between the objective lens and the electric field suppression electrode, positioned below the principal plane of the objective lens, having an opening through which the charged particle beam passes, and generating an electrostatic deflection field or an electrostatic pole field for the charged particle beam;
a boosting voltage source that applies a boosting voltage to the upper magnetic path;
a retarding voltage source that applies a retarding voltage to the sample, the lower magnetic path, and the electric field suppression electrode; and
a correction voltage source that generates an electrostatic deflection field or an electrostatic multipole field on the multipole electrode.

2. The charged particle beam device according to claim 1,
wherein the correction voltage source generates an electrostatic deflection field or an electrostatic pole field on the multipole electrode in such a manner as to cancel the electrostatic deflection field that is generated due to misalignment between the central axis of the electric field suppression electrode and the central axis of the objective lens.

3. The charged particle beam device according to claim 1,
wherein the correction voltage source generates an electrostatic deflection field and an electrostatic multipole field on the multipole electrode in such a manner as to cancel the electrostatic deflection field and electrostatic multipole field that are generated due to misalignment between the central axis of the electric field suppression electrode and the central axis of the objective lens.

4. The charged particle beam device according to claim 1,
wherein the electric field suppression electrode and the multipole electrode are each formed by a non-insulating and non-magnetic material.

5. The charged particle beam device according to claim 4,
wherein the electric field suppression electrode and multipole electrode are each formed by a single crystal silicon material, a molybdenum material, or a titanium material.

6. The charged particle beam device according to claim 1,
wherein a solid insulating material is sandwiched between the electric field suppression electrode and the multipole electrode and has an opening through which the charged particle beam passes.

7. The charged particle beam device according to claim 6,
wherein the inner diameter of the opening in the solid insulating material is larger than the inner diameter of the opening in the electric field suppression electrode and the inner diameter of the opening in the multipole electrode.

8. The charged particle beam device according to claim 7,
wherein a protrusion is provided in the solid insulating material side region and/or vacuum side region of a triple point of the electric field suppression electrode, the solid insulating material, and a vacuum on the surface of the electric field suppression electrode that faces the multipole electrode.

9. The charged particle beam device according to claim 7,
wherein a protrusion is provided in the solid insulating material side region and/or vacuum side region of a triple point of the multipole electrode, the solid insulating material, and a vacuum on the surface of the multipole electrode that faces the electric field suppression electrode.

10. The charged particle beam device according to claim 6,
wherein the solid insulating material is formed by an inorganic dielectric material.

11. The charged particle beam device according to claim 10,
wherein the solid insulating material is formed by silicon dioxide, aluminum oxide, steatite, sapphire, or zirconium dioxide.

12. The charged particle beam device according to claim 1,
wherein the height of the sample stage is changeable.

13. The charged particle beam device according to claim 1,
wherein, the output potential of the boosting voltage source, the retarding voltage source, and the correction voltage source is regarded as the reference potential during sample exchange.

14. The charged particle beam device according to claim 1, further comprising:
a control section that stores a table for registering the optical conditions of the charged particle optical system for a plurality of optical modes;
wherein the control section sets, in the charged particle optical system, the optical conditions for an optical mode selected from the plurality of optical modes; and
the optical conditions of the charged particle optical system include a boosting voltage value to be outputted from the boosting voltage source, a retarding voltage value to be outputted from the retarding voltage source, and a voltage value to be outputted from the correction voltage source to the multipole electrode.
